(19) United States
(12) Patent Application Publication
(10) Pub. No.: US 2017/0158993 A1
(43) Pub. Date: Jun. 8, 2017

(54) STABILIZATION OF TRIS(2 HYDROXYETHYL)METHYLAMMONIUM HYDROXIDE AGAINST DECOMPOSITION WITH DIALKYHYDROXYLAMINE

(71) Applicant: Cabot Microelectronics Corporation, Aurora, IL (US)

(72) Inventors: Roman IVANOV, Aurora, IL (US); Cheng-Yuan KO, Aurora, IL (US); Fred SUN, Aurora, IL (US)

(73) Assignee: Cabot Microelectronics Corporation, Aurora, IL (US)

(21) Appl. No.: 15/327,336

(22) PCT Filed: Jul. 17, 2015
(86) PCT No.: PCT/US2015/040871

§ 371 Date: Jan. 18, 2017

Related U.S. Application Data
(60) Provisional application No. 62/026,082, filed on Jul. 18, 2014.

(51) Int. Cl. C11D 11/00; C11D 7/32; H01L 21/02

(52) U.S. Cl. CPC C11D 11/0047; H01L 21/02074; C11D 7/3209; C11D 7/3218; C11D 7/3272

(57) ABSTRACT

The invention provides stabilized solutions useful as raw materials in various applications and methods for stabilizing such aqueous solutions with a stabilizer comprising one or more dialkylhydroxylamines or inorganic or organic acid salts thereof. Stabilized solutions and methods for stabilizing aqueous solutions thereof, include, for example, those of tris(2-hydroxy ethyl)methylammonium hydroxide (THEMAH) and/or carbohydrazide (CHZ).

### BACKGROUND OF THE INVENTION

It is common for a number of chemical ingredients to be put in solution to form raw materials that are then used in any of a variety of applications. When in solution form, however, sometimes the raw materials have a tendency to become unstable. Having an unstable raw material solution is not desirable because it can lead to a variety of problems such as shorter shelf-life, chemical decomposition, and an adverse impact on the efficacy and performance of the raw material solution.

For example, solutions of tris(2-hydroxyethyl)methylammonium hydroxide (THEMAH) are raw materials used in various applications, including cleaning compositions for use after chemical-mechanical polishing (CMP) of semiconductor wafers has taken place.

In this regard, a semiconductor wafer is typically composed of a substrate, such as a silicon wafer, on which a plurality of transistors has been formed. Transistors are chemically and physically connected into a substrate and are interconnected through the use of well known multilevel coplanar interconnects to form functional circuits. Typical multilevel interconnects are comprised of stacked thin-films consisting of, for example, one or more of the following: titanium (Ti), titanium nitrate (TiN), copper (Cu), aluminum (Al), tungsten (W), tantalum (Ta), or any combination thereof.

The traditional technique for forming functional multilevel coplanar interconnects has involved planarizing the surface of the interconnects via chemical-mechanical polishing (CMP). CMP involves the concurrent chemical and mechanical polishing of an overlying first layer to expose the surface of a non-planar second layer on which the first layer has been formed (see, e.g., U.S. Pat. Nos. 4,671,851; 4,910,155; 4,944,836; 6,592,776; 7,524,347; and 8,518,135).

Cleaning compositions are used because CMP processes tend to leave undesirable contaminants on the wafer surface. In particular, the nonmetal substrate (e.g., silicon dioxide) of the polished wafer is often contaminated with remnants of the polishing composition, such as silica or alumina abrasive particles, and with metal ions from the polishing composition and from the material being polished. Such contaminants can have a negative effect on semiconductor wafer performance As a result, after a polishing composition is applied to the semiconductor surface, the polishing composition typically is washed from the wafer surface with an aqueous cleaning solution after CMP is completed (see, e.g., U.S. Pat. Nos. 4,051,057; 5,334,332; 5,837,662; 5,981,454; 6,395,693; and 6,541,434 and U.S. Patent Publication 2009/0130849).

THEMAH, which can be used as a base in post-CMP cleaning compositions, however, is susceptible to oxidative degradation. This oxidative degradation is indicated by changes to the physical and chemical properties of the composition. Such changes include discoloration, the onset of bubbles through gassing, and/or negative pH drifting. These changes can occur particularly during storage, e.g., at ambient conditions. The rate of decomposition may increase at elevated temperatures.

Typically, to protect a solution against oxidative degradation, oxygen is displaced from a container with a flow of nitrogen gas. While this method slows down the process of decomposition, the presence of dissolved oxygen in the aqueous solution renders it ultimately ineffective. Alternatively, a stabilizing agent can be added to chemically prevent oxidative degradation. For example, THEMAH is typically supplied with several hundred ppm of the free-radical scavenger mono methyl ether of hydroquinone (MEHQ); but MEHQ has limited water solubility and is ineffective at low concentrations. Additionally, the presence of the additional organic component may affect the performance of the solution (e.g., a post-CMP cleaning composition).

Thus, there remains a need for a method for stabilizing an aqueous solution comprising THEMAH or other compounds and to related stabilized solutions.

### BRIEF SUMMARY OF THE INVENTION

In one aspect, the invention provides a method for stabilizing an aqueous solution of tris(2-hydroxyethyl)methylammonium hydroxide (THEMAH). The method comprises, consists of, or consists essentially of adding a stabilizer comprising one or more dialkylhydroxylamines or inorganic or organic acid salts thereof to the aqueous solution of THEMAH.

In another aspect, the invention provides a stabilized THEMAH solution. The solution comprises, consists of, or consists essentially of: THEMAH; water; and stabilizer comprising one or more dialkylhydroxylamines or inorganic or organic acid salts thereof.

In another aspect, the invention provides a method for stabilizing an aqueous solution of carbohydrazide (CHZ). The method comprises, consists of, or consists essentially of adding a stabilizer comprising one or more dialkylhydroxylamines or inorganic or organic acid salts thereof to the aqueous solution of CHZ.

In another aspect, the invention provides a stabilized CHZ solution. The solution comprises, consists of, or consists essentially of: CHZ; water; and stabilizer comprising one or more dialkylhydroxylamines or inorganic or organic acid salts thereof.

### BRIEF DESCRIPTION OF THE SEVERAL VIEWS OF THE DRAWINGS

FIG. 1, while not wishing to be bound by any particular theory, is a schematic depiction believed to illustrate a bio-oxidative degradation mechanism of tris(2-hydroxyethyl)methylammonium hydroxide (THEMAH).

FIG. 2 is a graph plotting copper loss in Angstroms (y-axis) over time in seconds (x-axis) of two cleaning compositions, one with diethylhydroxylamine (DEHA) and one without, where the two compositions are applied twice to a copper-coupon (4.1 cm by 4.1 cm), once upon preparation and again after four months as set forth in Example 2.

### DETAILED DESCRIPTION OF THE INVENTION

Embodiments of the invention provide stabilized solutions useful as raw materials in various applications and methods for stabilizing such aqueous solutions. Stabilized solutions and methods for stabilizing aqueous solutions thereof, include, for example, those of tris(2-hydroxyethyl)methylammonium hydroxide (THEMAH) and/or carbohydrazide (CHZ).

In particular, it has been found that a stabilizer comprising one or more dialkylhydroxylamines or inorganic or organic acid salts thereof can advantageously be added to an aqueous solution of THEMAH and/or CHZ. The inorganic or organic salts can be one or more of nitrate, phosphate, acetate, sulfate, hydrochloride, lactate, and glycolate. In preferred embodiments, the dialkylhydroxylamine is diethylhydroxylamine (DEHA). For ease of discussion, DEHA, at times, is the referenced stabilizer below, but it will be understood that the discussion applies to any other stabilizer mentioned above unless otherwise indicated.

### Applications for Raw Materials

Embodiments of the invention can be used in any suitable application. One such example is in cleaning compositions used to remove some or all of the contaminants after chemical-mechanical polishing (CMP) has taken place on a substrate. Such embodiments, where the stabilized raw materials (i.e., solutions) are used as cleaning compositions, have applicability with respect to a wide variety of semiconductor wafers used in fabrication of integrated circuits and other microdevices. Typically, the semiconductor wafer includes an insulator and a conducting agent. The stabilized raw materials in accordance with embodiments of the invention can be used to clean substrates containing a variety of such insulators and conducting agents.

For example, with some applications in accordance with embodiments of the invention, copper can be a suitable conducting agent and silicon oxide (e.g., carbon doped) can be used as an insulator. Other layers can be included to include titanium nitride, tantalum nitride, or reactive metal, such as cobalt metal, in order to enhance the interface between copper and, e.g., material having a relatively low dielectric constant relative to silicon dioxide, or other materials. It will be understood that the layers can be applied by any suitable method, such as chemical vapor deposition (CVD). Following CMP, the use of stabilized cleaning compositions prepared in accordance with embodiments of the invention desirably enhance conductivity by removing contaminants that would otherwise interfere with and hamper conductivity.

Although conventional CMP processes are suitable for polishing, they tend to leave undesirable contaminants on the wafer surface. Remnants from the polishing composition and process can result in debris that can be in the form of organic compounds, such as benzotriazole (BTA), silica, or other abrasive particles, surfactants, metal ions, polishing pad debris, CMP byproducts (e.g., metal adduct ions with organic ligands), or the like. Stabilized embodiments of the invention can be suitable to remove these undesirable contaminants.

### Stabilizing Agents

In accordance with embodiments of the invention, raw materials are stabilized with one or more dialkylhydroxylamines or inorganic or organic acid salts thereof, such as DEHA. Such dialkylhydroxylamines or inorganic or organic acid salts thereof, surprisingly and unexpectedly provide a stabilizing effect in raw material solutions, thereby expanding their shelf-life in some embodiments. In some embodiments, DEHA, in particular, has been found to exhibit a stabilizing effect because it significantly reduces raw material, e.g., THEMAH, decomposition as can be seen, for example, by lowered negative pH drift, as compared to raw material solutions absent DEHA or with such solutions with less amounts of DEHA.

This stabilizing effect can be seen in a variety of applications, such as post-CMP cleaning, photoresist removal, and/or raw chemical production and storage. In some embodiments of the invention, such as those where the stabilized raw materials (i.e., solutions) are used as cleaning compositions, DEHA can be used as an organic inhibitor, e.g., in cleaning compositions, that desirably improves anti-corrosiveness and/or scavenges active oxygen from transition metal surfaces.

DEHA can be present in any suitable amount in raw material solutions. In some embodiments, DEHA can be present in an amount of from about 0.002 wt. % to about 10 wt. %, such as from about 0.003 wt. % to about 5 wt. %, e.g., from about 0.003 wt. % to about 4 wt. %, from about 0.005 wt. % to about 5 wt. %, from about 0.2 wt. % to about 4 wt. %, from about 1 wt. % to about 3.5 wt. %, or from about 2 wt. % to about 3 wt. %. For example, in some embodiments, DEHA is in an amount of from about 0.001 wt. % to about 0.2 wt. % (0.002 wt. % to about 0.06 wt. %) when in a diluted form. Additionally, in some embodiments, DEHA is in an amount of from about 0.05 wt. % to about 20 wt. % (e.g., from about 0.1 wt. % to about 10 wt. %) when in a concentrated form.

In some embodiments comprising DEHA as a stabilizer, DEHA is present in a diluted form in an amount that is from about 0.001 wt. % to about 0.2 wt. %, e.g., from about 0.001 wt. % to about 0.01 wt. %, from about 0.001 wt. % to about 0.02 wt. %, from about 0.001 wt. % to about 0.03 wt. %, from about 0.001 wt. % to about 0.04 wt. %, from about 0.001 wt. % to about 0.05 wt. %, from about 0.001 wt. % to about 0.06 wt. %, from about 0.001 wt. % to about 0.08 wt. %, from about 0.001 wt. % to about 0.1 wt. %, from about 0.001 wt. % to about 0.12 wt. %, from about 0.001 wt. % to about 0.14 wt. %, from about 0.001 wt. % to about 0.16 wt. %, from about 0.001 wt. % to about 0.18 wt. %, from about 0.002 wt. % to about 0.01 wt. %, from about 0.002 wt. % to about 0.02 wt. %, from about 0.002 wt. % to about 0.03 wt. %, from about 0.002 wt. % to about 0.04 wt. %, from about 0.002 wt. % to about 0.05 wt. %, from about 0.002 wt. % to about 0.06 wt. %, from about 0.002 wt. % to about 0.08 wt. %, from about 0.002 wt. % to about 0.1 wt. %, from about 0.002 wt. % to about 0.12 wt. %, from about 0.002 wt. % to about 0.14 wt. %, from about 0.002 wt. % to about 0.16 wt. %, from about 0.002 wt. % to about 0.18 wt. %, from about 0.002 wt. % to about 0.2 wt. %, from about 0.003 wt. % to about 0.02 wt. %, from about 0.003 wt. % to about 0.03 wt. %, from about 0.003 wt. % to about 0.04 wt. %, from about 0.003 wt. % to about 0.05 wt. %, from about 0.003 wt. % to about 0.06 wt. %, from about 0.003 wt. % to about 0.08 wt. %, from about 0.003 wt. % to about 0.1 wt. %, from about 0.003 wt. % to about 0.12 wt. %, from about 0.003 wt. % to about 0.14 wt. %, from about 0.003 wt. % to about 0.16 wt. %, from about 0.003 wt. % to about 0.18 wt. %, from about 0.003 wt. % to about 0.2 wt. %, from about 0.005 wt. % to about 0.01 wt. %, from about 0.005 wt. % to about 0.02 wt. %, from about 0.005 wt. % to about 0.03 wt. %, from about 0.005 wt. % to about 0.04 wt. %, from about 0.005 wt. % to about 0.05 wt. %, from about 0.005 wt. % to about 0.06 wt. %, from about 0.005 wt. % to about 0.08 wt. %, from about 0.005 wt. % to about 0.1 wt. %, from about 0.005 wt. % to about 0.12 wt. %, from about 0.005 wt. % to about 0.14 wt. %, from about 0.005 wt. % to about 0.16 wt. %, from about 0.005 wt. % to about 0.18 wt. %, or from about 0.005 wt. % to about 0.2 wt. %.

In some embodiments comprising DEHA as a stabilizer, DEHA is present in a concentrated form in an amount that is from about 0.05 wt. % to about 20 wt. %, e.g., from 0.05 wt. % to about 0.5 wt. %, from about 0.05 wt. % to about 1 wt. %, from about 0.05 wt. % to about 2 wt. %, from about 0.05 wt. % to about 4 wt. %, from about 0.05 wt. % to about 8 wt. %, from about 0.05 wt. % to about 12 wt. %, from about 0.05 wt. % to about 16 wt. %, from about 0.1 wt. % to about 0.5 wt. %, from about 0.1 wt. % to about 1 wt. %, from about 0.1 wt. % to about 2 wt. %, from about 0.1 wt. % to about 4 wt. %, 0.1 wt. % to about 8 wt. %, from about 0.1 wt. % to about 12 wt. %, from about 0.1 wt. % to about 16 wt. %, from about 0.1 wt. % to about 20 wt. %, from about 0.5 wt. % to about 1 wt. %, from about 0.5 wt. % to about 2 wt. %, from about 0.5 wt. % to about 4 wt. %, from about 0.5 wt. % to about 8 wt. %, from about 0.5 wt. % to about 12 wt. %, from about 0.5 wt. % to about 16 wt. %, from about 0.5 wt. % to about 20 wt. %, from about 1 wt. % to about 2 wt. %, from about 1 wt. % to about 4 wt. %, from about 1 wt. % to about 12 wt. %, from about 1 wt. % to about 16 wt. %, from about 1 wt. % to about 20 wt. %, from about 2 wt. % to about 4 wt. %, 2 wt. % to about 8 wt. %, from about 2 wt. % to about 12 wt. %, from about 2 wt. % to about 16 wt. %, or from about 2 wt. % to about 20 wt. %.

It will be understood that, generally, the actual quantity of one or more ingredient in stabilized solutions useful as raw materials in various applications and methods for stabilizing such aqueous solutions prepared in accordance with embodiments of the invention (e.g., THEMAH, CHZ, and/or one or more dialkylhydroxylamines or inorganic or organic acid salts thereof, such as DEHA) may vary depending on the degree of desired dilution or concentration. In this respect, some embodiments can be packaged in the form of a concentrate where water can be later added to dilute the solution, such as at a point of use (e.g., by an end user), or the solution can be packaged in a diluted form with water already included. For example, in some embodiments, the concentrated forms of each ingredient and/or the solution as a whole can facilitate ease of shipping, distribution, and sale. However in other embodiments, each ingredient and/or the solution as a whole can be in a diluted form, e.g., to simplify end use. Thus, the weight ranges as described herein and throughout for the aforementioned ingredients can refer to either the diluted or concentrated ranges.

Accordingly, each ingredient, such as DEHA, can be present in a diluted form that is suitable for end use or in a form that is concentrated and then diluted (e.g., 2 times, 5 times, 10 times, 25 times, 40 times, 50 times, 60 times, 70 times, 100 times, 125 times, 150 times, 175 times, 200 times, etc. to the diluted form). When the concentrate is diluted with an equal volume of water (e.g., 1 equal volumes water, 4 equal volumes of water, 9 equal volumes of water, 24 equal volumes of water, 39 equal volumes of water, 49 equal volumes of water, 59 equal volumes water, 69 equal volumes of water, 99 equal volumes of water, 124 equal volumes of water, 149 equal volumes of water, 174 equal volumes of water, or 199 equal volumes of water, respectively), each ingredient will be present in embodiments of the invention in an amount within the diluted ranges set forth below for each component. Furthermore, as will be understood by those of ordinary skill in the art, the concentrate can contain an appropriate fraction of the water present in the final solution. For example, in some applications, e.g., cleaning compositions, the concentrate can contain an appropriate fraction of the water present in the final cleaning composition in order to ensure that the compound or compounds that increases the generation of low final metal surface roughness, corrosion, and/or the effective removal of contaminants, such as abrasive particles, metal ions, and other residues as discussed herein are at least partially or fully dissolved in the concentrate.

### Stabilized Solutions of THEMAH and Methods for Stabilizing Solutions Thereof

DEHA can be used, for example, to stabilize THEMAH, a base used in a variety of applications, e.g., cleaning compositions. THEMAH is desirable for use in cleaning compositions because it is a readily available raw material and has been found to have chelating properties. In cleaning compositions, THEMAH, a quaternary ammonium hydroxide, can be used as a bulky protecting ligand, which desirably generates low final metal surface roughness and/or effectively removes contaminants, including remnants of the polishing composition, such as silica or alumina abrasive particles or the like, metal ions from the polishing composition and from the material being polished, polishing pad debris, CMP-byproducts, surfactants, and other residues, e.g., organic residues such as BTA. THEMAH can be used alone or in combination with other bulky protecting ligands. Without desiring to be bound to any particular theory, it is believed that DEHA is able to prevent oxidative degradation in THEMAH. For example, it has been found that in accordance with embodiments of the invention, DEHA prevents negative pH drift in solutions containing THEMAH.

In embodiments where THEMAH is used as a raw material to be stabilized, it can be present in any suitable amount. For example, THEMAH can be present in an amount of from about 0.01 wt. % to about 48 wt. %, such as from about 0.2 wt. % to about 35 wt. %, e.g., from about 1 wt. % to about 25 wt. %, from about 1.5 wt. % to about 15 wt. %, from about 2 wt. % to about 10 wt. %, from about 2.5 wt. % to about 7 wt. %, or from about 3 wt. % to about 6 wt. %. For example, in some embodiments, THEMAH is in an amount of from about 0.01 wt. % to about 0.8 wt. % when in a diluted form. Additionally, in some embodiments, THEMAH is in an amount of from about 1 wt. % to about 30 wt. % when in a concentrated form.

In some embodiments where THEMAH is used as a raw material to be stabilized, THEMAH is present in a diluted form in an amount that is from about 0.01 wt. % to about 0.8 wt. %, e.g., from about 0.01 wt. % to about 0.3 wt. %, from about 0.01 wt. % to about 0.5 wt. %, from about 0.05 wt. % to about 0.3 wt. %, from about 0.05 wt. % to about 0.8 wt. %, from about 0.1 wt. % to about 0.3 wt. %, from about 0.1 wt. % to about 0.5 wt. %, from about 0.1 wt. % to about 0.8 wt. %, from about 0.2 wt. % to about 0.3 wt. %, from about 0.2 wt. % to about 0.5 wt. %, or from about 0.2 wt. % to about 0.8 wt. %.

In some embodiments where THEMAH is used as a raw material to be stabilized, THEMAH is present in a concentrated form in an amount that is from about 1 wt. % to about 30 wt. %, e.g., from about 1 wt. % to about 10 wt. %, from about 1 wt. % to about 15 wt. %, from about 1 wt. % to about 20 wt. %, from about 1 wt. % to about 25 wt. %, from about 3 wt. % to about 10 wt. %, from about 3 wt. % to about 15 wt. %, from about 3 wt. % to about 20 wt. %, from about 3 wt. % to about 25 wt. %, from about 3 wt. % to about 30 wt. %, from about 5 wt. % to about 10 wt. %, from about 5 wt. % to about 15 wt. %, from about 5 wt. % to about 20 wt. %, from about 5 wt. % to about 25 wt. %, from about 5 wt. % to about 30 wt. %, from about 7 wt. % to about 10 wt. %., from about 7 wt. % to about 15 wt. %, from about 7 wt. % to about 20 wt. %, from about 7 wt. % to about 25 wt. %, or from about 7 wt. % to about 30 wt. %.

### Stabilized Solutions of CHZ and Methods for Stabilizing Solutions Thereof

DEHA can be used, for example, to stabilize CHZ, an antioxidant oxygen scavenger used in a variety of applications, e.g., cleaning compositions. CHZ can be used alone or in combination with other bulky protecting ligands (e.g., THEMAH). Without desiring to be bound to any particular theory, it is believed that DEHA is able to prevent oxidative degradation in CHZ. For example, it has been found that in accordance with embodiments of the invention, DEHA prevents discoloration and the formation of bubbles, which signify oxidation, in solutions containing CHZ.

In some embodiments where CHZ is used as a raw material to be stabilized, CHZ can be present in an amount of from about 0.01 wt. % to about 18.0 wt. %, such as from about 0.02 wt. % to about 12 wt. %, e.g., from about 0.05 wt. % to about 6 wt. %, from about 0.1 wt. % to about 4 wt. %, from about 1 wt. % to about 3.5 wt. %, or from about 2 wt. % to about 3 wt. %. For example, in some embodiments, CHZ is in an amount of from about 0.01 wt. % to about 0.04 wt. % when in a diluted form. Additionally, in some embodiments, CHZ is in an amount of from about 0.5 wt. % to about 12 wt. % when in a concentrated form.

In some embodiments where CHZ is used as a raw material to be stabilized, CHZ is present in a diluted form in an amount that is from about 0.01 wt. % to about 0.04 wt. %, e.g., from about 0.01 wt. % to about 0.02 wt. %, from about 0.01 wt. % to about 0.03 wt. %, from about 0.02 wt. % to about 0.03 wt. %, from about 0.02 wt. % to about 0.04 wt. %, or from about 0.03 wt. % to about 0.04 wt. %.

In some embodiments where CHZ is used as a raw material to be stabilized, CHZ is present in a concentrated form in an amount that is from about 0.5 wt. % to about 12 wt. %, e.g., from about 0.5 wt. % to about 3 wt. %, from about 0.5 wt. % to about 5 wt. %, from about 0.5 wt. % to about 8 wt. %, from about 0.5 wt. % to about 10 wt. %, from about 1 wt. % to about 3 wt. %, from about 1 wt. % to about 5 wt. %, from about 1 wt. % to about 8 wt. %, from about 1 wt. % to about 10 wt. %, from about 1 wt. % to about 12 wt. %, from about 2 wt. % to about 3 wt. %, from about 2 wt. % to about 5 wt. %, from about 2 wt. % to about 8 wt. %, from about 2 wt. % to about 10 wt. %, or from about 2 wt. % to about 12 wt. %.

CHZ can be stabilized either alone or along with THEMAH. As such, the above weight percentages apply to solutions of CHZ with or without THEMAH or other raw material active ingredients.

### Weight Ratios

The stabilizing agent can be provided in any suitable weight ratio with the raw material active ingredient to be stabilized. To illustrate, suitable weight ratios of stabilizers and active ingredients can be seen from the weight ratios provided below for the ratios of THEMAH to DEHA and CHZ to DEHA provided below. However, it will be understood that similar ratios can be readily applied to other raw material active ingredient and stabilizer combinations in accordance with embodiments of the invention.

In some embodiments, the weight ratio of THEMAH to DEHA can be from about 0.5:1 to about 50:1, such as from about 0.5:1 to about 40:1, e.g., from about 0.5:1 to about 33:1, from about 0.5:1 to about 30:1, from about 0.5:1 to about 25:1, from about 0.5:1 to about 20:1, from about 0.5:1 to about 15:1, from about 0.5:1 to about 10:1, from about 0.5:1 to about 8:1, from about 0.5:1 to about 6:1, from about 0.5:1 to about 5:1, from about 0.5:1 to about 4.5:1, from about 0.5:1 to about 4:1, from about 0.5:1 to about 3:1, from about 0.5:1 to about 2:1, from about 0.5:1 to about 1:1, from about 0.5:1 to about 1:1, from about 1:1 to about 50:1 from about 1:1 to about 40:1, from about 1:1 to about 33:1, from about 1:1 to about 30:1, from about 1:1 to about 25:1, from about 1:1 to about 20:1, from about 1:1 to about 15:1, from about 1:1 to about 10:1, from about 1:1 to about 8:1, from about 1:1 to about 6:1, from about 1:1 to about 5:1, from about 1:1 to about 4.5:1, from about 1:1 to about 4:1, from about 1:1 to about 3:1, from about 1:1 to about 2:1, from about 1:1 to about 1.7:1, from about 1.7:1 to about 50:1 from about 1.7:1 to about 40:1, from about 1.7:1 to about 33:1, from about 1.7:1 to about 30:1, from about 1.7:1 to about 25:1, from about 1.7:1 to about 20:1, from about 1.7:1 to about 15:1, from about 1.7:1 to about 10:1, from about 1.7:1 to about 8:1, from about 1.7:1 to about 6:1, from about 1.7:1 to about 5:1, from about 1.7:1 to about 4.5:1, from about 1.7:1 to about 4:1, from about 1.7:1 to about 3:1, from about 1.7:1 to about 2:1, from about 3:1 to about 50:1 from about 3:1 to about 40:1, from about 3:1 to about 33:1, from about 3:1 to about 30:1, from about 3:1 to about 25:1, from about 3:1 to about 20:1, from about 3:1 to about 15:1, from about 3:1 to about 10:1, from about 3:1 to about 9:1, from about 3:1 to about 8:1, from about 3:1 to about 7:1, from about 3:1 to about 6:1, from about 3:1 to about 5:1, from about 3:1 to about 4.5:1, from about 3:1 to about 4:1, or from about 3:1 to about 3.5:1.

In some embodiments, the weight ratio of CHZ to DEHA can be from about 3:1 to about 10:1, such as from about 3:1 to about 9:1, e.g. from about 3:1 to about 8:1 from about 3:1 to about 7:1, from about 3:1 to about 6:1, from about 3:1 to about 5:1, from about 3:1 to about 4:1, from about 3:1 to about 3.5:1, from about 3.5:1 to about 10:1, from about 3.5:1 to about 9:1, e.g. from about 3.5:1 to about 8:1 from about 3.5:1 to about 7:1, from about 3.5:1 to about 6:1, from about 3.5:1 to about 5:1, from about 3.5:1 to about 4:1, from about 4:1 to about 10:1, from about 4:1 to about 9:1, from about 4:1 to about 8:1, from about 4:1 to about 7:1, from about 4:1 to about 9:1, from about 4:1 to about 8:1 from about 4:1 to about 7:1, from about 4:1 to about 6:1, or from about 4:1 to about 5:1.

### Water

The inventive stabilized solution contains water, which can be present in any suitable amount. For example, water can be present in the stabilized solution, as used for a suitable application, such as to clean a substrate after CMP has taken place, in an amount of from about 50.0 wt. % to about 99.99 wt. %, e.g., from about 50 wt. % to about 40 wt. %, from about 40 wt. % to about 5 wt. %, from about 5 wt. % to about 0.1 wt. %, or from about 0.1 wt. % to about 0.01 wt. %, all as based on the total weight of the stabilized solution.

In the concentrated form of the stabilized solution, some amount of water could be included in some embodiments of the inventive stabilized solution, such as in an amount of from about 45 wt. % to about 99 wt. %, e.g., from about 50 wt. % to about 95 wt. %, from about 60 wt. % to about 90 wt. %, from about 70 wt. % to about 85 wt. %, or from about 75 wt. % to about 80 wt. %.

### Properties

Surprisingly and unexpectedly, embodiments of the invention provide stabilized solutions of raw materials that have relatively long shelf-life and avoid oxidative degradation. For example, in various embodiments, stabilized solutions of the invention resist changes to physical and chemical properties, such as discoloration, onset of bubbles through gassing, and/or negative pH drifting, e.g., at ambient or even elevated temperatures.

In some embodiments, stabilized solutions of the invention are stable for at least about one month, such as at least about two months or more, e.g., at least about three months or more, at least about four months or more, at least about five months or more, at least about six months or more, at least about seven months or more, at least about eight months or more, at least about nine months or more, at least about ten months or more, at least about eleven months or more, at least about twelve months or more, at least about thirteen months or more, at least about fourteen months or more, at least about fifteen months or more, at least about sixteen months or more, at least about seventeen months or more, at least about eighteen months or more, at least about nineteen months or more, at least about twenty months or more, at least about twenty-one months or more, at least about twenty-two months or more, at least about twenty-three months or more, or at least about twenty-four months or more.

Surprisingly and unexpectedly, some embodiments of the invention also desirably avoid negative pH drift. In this regard, negative pH drift indicates decomposition that adversely alters the base concentration of the solution. For example, some embodiments have a pH drift of about 0.5 or less, such as about 0.45 or less, e.g., about 0.4 or less, about 0.35 or less, about 0.3 or less, about 0.25 or less, about 0.2 or less, about 0.15 or less, about 0.1 or less, about 0.05 or less, about 0.01 or less, or no pH drift.

### Nitrogen Protection

In some embodiments, it has surprisingly and unexpectedly been found that adding nitrogen protection advantageously affects the length of stability with regards to the amount of stabilizer required in the solution. Nitrogen protection has not been known to be very effective in stabilizing solutions of THEMAH and/or CHZ absent stabilizer of embodiments of the invention. According to embodiments of the invention, the present invention demonstrates that, when nitrogen protection is added in addition to a stabilizer in the form of a dialkylhydroxylamine, e.g., DEHA, a smaller amount of the stabilizer is required to achieve a comparable length of stability as a solution without nitrogen protection and a larger quantity of the stabilizer. In some embodiments, nitrogen protection in the form of nitrogen gas as a “pillow” or “blanket” in a container overlying the stabilized solution advantageously and synergistically further stabilizes the raw material solution.

### Mechanism of Instability

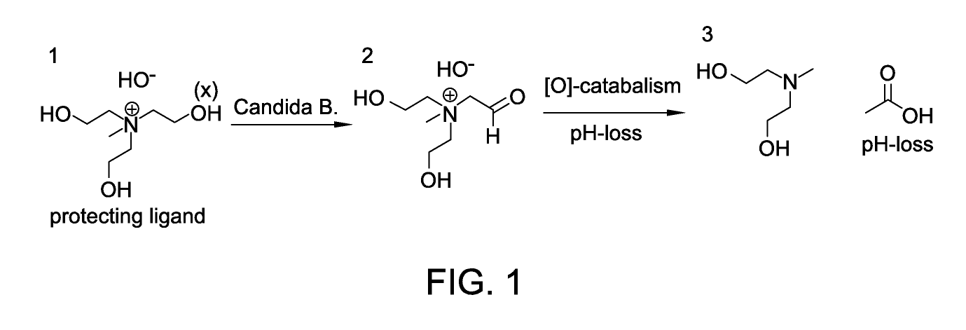

Reference is now made to FIG. 1. While not wishing to be bound by any particular theory, representations 1-3 illustrate a mechanism believed to be associated with instability of solutions of THEMAH raw materials.

Representation 1 illustrates a THEMAH molecule. The THEMAH molecule comes into contact with Candida bacteria (“Candida B”), a possible effect of which is shown in representation 2. It is believed that common bacteria, such as Candida B, can oxidize —OH group (x) through an enzymatic mechanism and transform it into an aldehyde group. It is further believed that, through a second enzymatic mechanism, Candida B can cleave the bond between the nitrogen and the aldehyde group and oxidize the aldehyde group as illustrated in representation 3. Accordingly, the THEMAH molecule becomes a non-charged amine with two —H groups that is no longer a base. The aldehyde group is believed to be transformed into acetaldehyde, which immediately oxidizes, producing acetic acid with high pH. The acetic acid reacts with the non-charged amine, neutralizing it and producing a salt. One possible effect of such a reaction is a loss of basicity.

It is further believed that, in some embodiments, a by-product of THEMAH decomposition further reacts with CHZ, which renders a pink color to the solution. The oxidative decomposition of CHZ produces CO₂ and N₂ bubbles and a lower concentration of CHZ because a significant amount of CHZ is decomposed indicating oxidative decomposition.

To combat and overcome this instability, it is believed that dialkylhydroxylamines, such as DEHA, or inorganic or organic acid salts thereof stabilize solutions containing THEMAH by either scavenging activated oxygen or blocking bacterial enzyme, thereby preventing this oxidative decomposition that causes negative pH drift. While not wishing to be bound by any particular theory, it is believed that, for example, DEHA may inhibit bacterial enzyme required for oxidation of an hydroxyalkyl (e.g., hydroxyethyl) substituent in THEMAH to corresponding aldehyde, such that, in some embodiments, DEHA has been found to exhibit a stabilizing effect.

### Method of Cleaning

Embodiments of the invention used as cleaning compositions (i.e., solutions) for use after CMP has taken place, can be applied by any suitable method. For example, one such cleaning method comprises, consists of, or consists essentially of (a) providing a semiconductor wafer having contaminants resulting from chemical-mechanical polishing of the semiconductor wafer and (b) contacting the surface of the semiconductor wafer with a cleaning composition as described herein to remove at least some of the contaminants from the surface of the semiconductor wafer. As noted herein, the contaminants can include, for example, abrasive particles, organic residue, metal ions, pad debris and CMP-byproducts, or any combination thereof. The wafer can include a low-k dielectric material and/or metal conductors.

Furthermore, a method for polishing and cleaning the surface of a semiconductor wafer comprises, consists of, or consists essentially of: (a) providing a polishing pad, a chemical-mechanical polishing composition, and a semiconductor wafer; (b) contacting the semiconductor wafer with the polishing pad and the polishing composition; (c) moving the polishing pad relative to a surface of the semiconductor wafer with the polishing composition therebetween to abrade the surface of the semiconductor wafer and thereby polish the surface of the wafer such that the polished surface of the wafer contains contaminants from the chemical-mechanical polishing composition; and (d) contacting the polished surface of the semiconductor wafer that contains contaminants with a cleaning composition as described herein to remove at least some of the contaminants from the polished surface of the semiconductor wafer.

Typically a chemical-mechanical polishing composition will be utilized in the polishing of a semiconductor wafer with a polishing pad, such that the method of polishing and cleaning a semiconductor wafer further comprises providing a chemical-mechanical polishing composition between the polishing pad and the semiconductor wafer, contacting the semiconductor wafer with the polishing pad with the polishing composition therebetween, and moving the polishing pad relative to the semiconductor wafer with the polishing composition therebetween to abrade the semiconductor wafer and thereby polish the semiconductor wafer. Embodiments of the invention are not limited by the polishing composition, which can be any suitable polishing composition as known in the art. Additionally, embodiments of the invention is not limited by the CMP apparatus and polishing pad used during polishing, which can be any suitable CMP apparatus and polishing pad, many of which are known in the art.

Generally, chemical-mechanical polishing apparatus comprises (a) a platen that rotates; (b) a polishing pad disposed on the platen; and (c) a carrier that holds a semiconductor wafer to be polished by contacting the rotating polishing pad. In some embodiments, the apparatus further comprises (d) means for delivering a chemical-mechanical polishing composition between the polishing pad and the semiconductor wafer. For example, the means for delivering the chemical-mechanical polishing composition can include, for example, a pump and flow metering system.

The following examples further illustrate the invention but, of course, should not be construed as in any way limiting its scope.

### EXAMPLE 1

This Example demonstrates the benefit of using a dialkylhydroxylamine, in this case diethylhydroxylamine (DEHA), in a post-CMP cleaning composition comprising tris(2-hydroxyethyl)methylammonium hydroxide (THEMAH) and carbohydrazide (CHZ). Each sample was prepared in the amount of 3.5 liters in a one gallon (3.589 liters) plastic container. The aqueous solution comprised 20 wt. % of THEMAH, 6 wt. % of CHZ, and from 0.6 wt. % to 6 wt. % of DEHA. The remaining 0.089 liters were filled with either oxygen or nitrogen depending on the sample.

Table 1 illustrates the efficacy of DEHA as a stabilizing agent. Table 1 notes the wt. % of DEHA added, whether or not nitrogen protection was added, the number of days for which the sample was observed, the appearance of the sample with regards to the level of discoloration and the presence of bubbles, and the change in pH. In Table 1, where it indicates nitrogen protection, it will be understood that nitrogen was added to displace oxygen.

TABLE 1
Discoloration and pH-drift of THEMAH-based compositions
stabilized by DEHA

| | DEHA | Nitrogen | Time | | Change in |
|---|---|---|---|---|---|
| Sample | wt. % | Protection | Elapsed | Appearance | pH |
| 1A | 0.6 wt. % | No | 4 days | Pink color, lots of | 0.5 |
| | | | | bubbles | |
| 1B | 0.6 wt. % | Yes | 4 days | Slight pink color, | 0.2 |
| | | | | a few bubbles | |
| 1C | 2.0 wt. % | No | 4 days | Colorless, | <0.2 |
| | | | | no bubbles | |
| 1D | 2.0 wt. % | Yes | 4 days | Colorless | <0.2 |
| 1E | 6.0 wt. % | No | 4 days | Colorless | <0.2 |
| 1F | 6.0 wt. % | Yes | 4 days | Colorless | <0.2 |
| 1G | 0.6 wt. % | No | 7 days | Deep pink color, | 0.7 |
| | | | | lots of bubbles | |
| 1H | 0.6 wt. % | Yes | 7 days | Pink color, | 0.4 |
| | | | | lots of bubbles | |
| 1I | 2.0 wt. % | No | 7 days | Colorless | <0.2 |
| 1J | 2.0 wt. % | Yes | 7 days | Colorless | <0.2 |
| 1K | 6.0 wt. % | No | 7 days | Colorless | <0.2 |
| 1L | 6.0 wt. % | Yes | 7 days | Colorless | <0.2 |
| 1M | 0.6 wt. % | No | 1 month | Deep pink color, | 1.1 |
| | | | | lots of bubbles | |
| 1N | 0.6 wt. % | Yes | 1 month | Deep pink color, | 0.8 |
| | | | | lots of bubbles | |
| 1O | 2.0 wt. % | No | 1 month | Slight pink color, | 0.3 |
| | | | | a few bubbles | |
| 1P | 2.0 wt. % | Yes | 1 month | Colorless | <0.2 |
| 1Q | 6.0 wt. % | No | 1 month | Colorless | <0.2 |
| 1R | 6.0 wt. % | Yes | 1 month | Colorless | <0.2 |

Any change in appearance or substantial pH drifting signifies decomposition of the THEMAH base and CHZ. When the pH drift was negligible, i.e., 0.5 or less, and the appearance of the sample is unchanged, the THEMAH base and CHZ are stable. Samples 1G, 1M, and 1N showed significant discoloration and the accumulation of numerous bubbles as well as unacceptable negative pH drift. Samples 1A-1F, 1H-1L, and 1O-1R showed minimal or no discoloration, the accumulation of very few or no bubbles, and negligible negative pH drift.

### EXAMPLE 2

This Example demonstrates the benefit of using a dialkylhydroxylamine, in this case diethylhydroxylamine (DEHA), in a post-CMP cleaning composition comprising tris(2-hydroxyethyl)methylammonium hydroxide (THEMAH) and carbohydrazide (CHZ) with regards to cleaning ability measured by the amount of copper removed (copper loss) during post-CMP cleaning. The more copper that is removed from the substrate being polished by the application of the cleaning solution, the more corrosive the cleaning solution is. Higher corrosiveness can lead to unwanted defects on the substrate being polished, including pit defects (i.e., localized erosion), corrosion defects (i.e., widespread erosion), and higher roughness.

Both sample post-CMP cleaning solutions were prepared with 5 wt. % of THEMAH, 2 wt. % of organic amine, monoethanolamine (MEA), and 1.5 wt. % of CHZ. Sample 2A included 0.5 wt. % of DEHA, whereas Sample 2B was prepared without DEHA. Nitrogen protection was added to both samples. The composition of each sample is illustrated in Table 2 below.

TABLE 2
Examples of post-CMP cleaning compositions based
on THEMAH

| Sample | THEMAH wt. % | MEA wt. % | CHZ wt. % | DEHA wt. % |
|---|---|---|---|---|
| 2A | 5 wt. % | 2 wt. % | 1.5 wt. % | 0.5 wt. % |
| 2B | 5 wt. % | 2 wt. % | 1.5 wt. % | — |

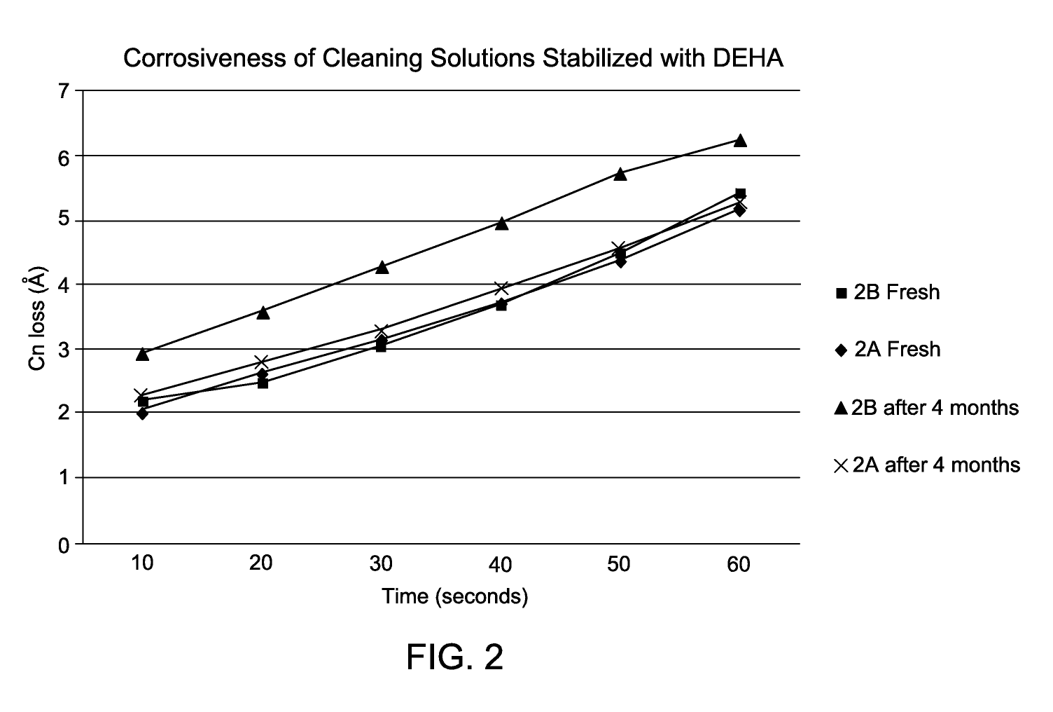

Samples 2A and 2B were tested by treating a copper-coupon (4.1 cm by 4.1 cm). For each sample, the amount of copper removed, measured in Angstroms, over a period of time, measured in seconds, was measured twice, once upon preparation (“fresh”) and again after four months. FIG. 2 illustrates the results of the test.

As can be observed from FIG. 2, Samples 2A and 2B exhibited similar copper loss over the course of sixty seconds when tested upon preparation of the cleaning solution. However, Sample 2A, which included DEHA, exhibited considerably less copper loss than Sample 2B, which did not include DEHA, when tested the second time after four months. In fact, Sample 2A exhibited little change in performance after four months.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A method for stabilizing an aqueous solution of tris(2-hydroxyethyl)methylammonium hydroxide (THEMAH) comprising adding a stabilizer comprising one or more dialkylhydroxylamines or inorganic or organic acid salts thereof to the aqueous solution of THEMAH.

2. The method of claim 1, wherein the dialkyhydroxylamine is diethylhydroxylamine (DEHA).

3. The method of claim 2, wherein the weight ratio of THEMAH to DEHA is from about 0.5:1 to about 50:1.

4. The method of claim 2, wherein the weight ratio of THEMAH to DEHA is from about 1:1 to about 33:1.

5. The method of claim 2, wherein the weight ratio of THEMAH to DEHA is from about 1.7:1 to about 25:1.

6. The method of claim 2, wherein the weight ratio of THEMAH to DEHA is from about 3:1 to about 10:1.

7. The method of claim 1, wherein the inorganic or organic salts are one or more of nitrate, phosphate, acetate, sulfate, hydrochloride, lactate, and glycolate.

8. The method of claim 1, wherein the amount of THEMAH is from about 0.01 wt. % to about 48 wt. %.

9. The method of claim 1, wherein the amount of DEHA is from about 0.003 wt. % to about 5 wt. %.

10. The method of claim 1, wherein the solution further comprises carbohydrazide (CHZ).

11. The method of claim 10, wherein the amount of CHZ is from about 0.02 wt. % to about 12 wt. %.

12-14. (canceled)

15. A stabilized tris(2-hydroxyethyl)methylammonium hydroxide (THEMAH) solution comprising:
THEMAH;
water; and
stabilizer comprising one or more dialkylhydroxylamines or inorganic or organic acid salts thereof.

16. The stabilized solution of claim 12, wherein the dialkyhydroxylamine is diethylhydroxylamine (DEHA).

17. The stabilized solution of claim 13, wherein the weight ratio of THEMAH to DEHA is from about 0.5:1 to about 50:1.

18. The stabilized solution of claim 13, wherein the weight ratio of THEMAH to DEHA is from about 1:1 to about 33:1.

19. The stabilized solution of claim 13, wherein the weight ratio of THEMAH to DEHA is from about 1.7:1 to about 25:1.

20. The stabilized solution of claim 13, wherein the weight ratio of THEMAH to DEHA is from about 3:1 to about 10:1.

21. The stabilized solution of claim 13, wherein the inorganic or organic salts are one or more of nitrate, phosphate, acetate, sulfate, hydrochloride, lactate, and glycolate.

22. The stabilized solution of claim 13, wherein the amount of THEMAH is from about 0.01 wt. % to about 48 wt. %.

23. The stabilized solution of claim 13, wherein the amount of DEHA is from about 0.003 wt. % to about 5 wt. %.

24. The stabilized solution of claim 13, wherein the solution further comprises carbohydrazide (CHZ).

25. The stabilized solution of claim 21, wherein the amount of CHZ is from about 0.02 wt. % to about 12 wt. %.

26-42. (canceled)
